(19) United States
(12) Patent Application Publication
(10) Pub. No.: US 2005/0064346 A1
(43) Pub. Date: Mar. 24, 2005

(54) Method for forming resist pattern, method for manufacturing master information carrier, magnetic recording medium, and magnetic recording/reproducing apparatus, and magnetic recording/reproducing apparatus

(75) Inventors: Terumi Yanagi, Osaka-shi (JP); Masaya Sakaguchi, Katano-shi (JP)

Correspondence Address: MERCHANT & GOULD PC, P.O. BOX 2903, MINNEAPOLIS, MN, 55402-0903, US

(73) Assignee: MATSUSHITA ELECTRIC INDUSTRIAL CO., LTD., Kadoma-shi (JP)

(21) Appl. No.: 10/944,301

(22) Filed: Sep. 17, 2004

(30) Foreign Application Priority Data
Sep. 19, 2003 (JP) 2003-328630

(51) Int. Cl. G03F 7/20

(52) U.S. Cl. 430/320; 430/322; 430/394

(57) ABSTRACT

The present invention provides a method for forming a resist pattern that allows a fine pattern to be formed by preventing undesirable diffraction of light in exposure. This method includes: a step of forming a resist film 2 on a surface of a base 1; a step of forming a protrusion 252 and an air-evacuating recess 251 on the resist film 2 by exposing the resist film 2 to light and developing the same; a step of bringing the resist film 2 and a photomask 31 in which a predetermined pattern is formed into close contact with each other by performing evacuation through the air-evacuating recess 251 in the state where the photomask 31 is superimposed on the resist film 2; and a step of exposing a portion of the resist film 2 that corresponds to the pattern of the photomask 31 to light, wherein the pattern of the photomask 31 is formed so as to extend from a region facing the protrusion 252 to a region facing the air-evacuating recess 251 on the resist film 2.

### BACKGROUND OF THE INVENTION

1. Field of the Invention

The present invention relates to a method for forming a resist pattern in the manufacture of a master information carrier or the like for use in recording digital information signals onto a magnetic recording medium.

2. Description of the Related Art

At present, the recording density of magnetic recording/reproducing apparatuses is increasing to achieve a small size and a large capacity. In the field of hard disk drives, which are typical magnetic recording/reproducing apparatuses, an a real recording density of more than 93 Mbit/mm² is already available on the market, and the technology is proceeding at such a rapid pace that, at present, an areal recording density of 155 Mbit/mm² is expected to be put to practical use.

Part of the technical background that has enabled such a high recording density is an increase in linear recording density resulting from an improvement in performance of magnetic recording media and head-disk interfaces, and new signal processing methods such as partial response. However, in recent years, the rate of increase in track density exceeds the rate of increase in linear recording density, and has become a primary factor of an increase in areal recording density.

This is because a thin-film magnetic head using a magnetoresistive element (MR element) or a giant magnetoresistive element (GMR element), whose reproduction output performance is superior to that of conventional inductive-type magnetic heads, has been put to practical use. At present, it is possible to reproduce signals from tracks having a width of not more than 1 μm with a high S/N ratio by using a GMR head. Moreover, it is expected that, with a further improvement in head performance, the track pitch will be reduced further in the future.

To reproduce a signal with a high S/N ratio by scanning such a narrow track precisely with a magnetic head, a tracking servo technique for the magnetic head plays an important role. Such a tracking servo technique is disclosed in detail in, for example, “High-precision Servo Technique for Magnetic Disk Apparatus” (written by YAMAGUCHI, Journal of the Magnetics Society of Japan, vol. 20, No. 3, p. 771, 1996). According to this reference, in a current hard disk drive, there are regions disposed at predetermined angular intervals over the entire circumference of a disk, i.e., 360 degrees, and signals such as a tracking servo signal, an address information signal, and a reproduction clock signal are recorded in these regions (hereinafter, referred to as “preformat”).

A magnetic head can scan a track precisely while identifying and correcting its position by reproducing these signals at predetermined intervals. The above-mentioned signals such as the tracking servo signal, the address information signal, and the reproduction clock signal serve as reference signals for precisely scanning a track with the head. Therefore, high positioning accuracy is required for recording these signals. According to “The Current State and Prospects of Mechanical Servo and HDI Technique” (written by UEMATSU et al., the documents of the 93rd Symposium of the Magnetics Society of Japan, 93-5, p. 35, 1996), for example, a current hard disk drive performs preformat recording with a magnetic head whose position is controlled precisely, using a special servo track writing device after disks are incorporated into the drive.

However, the above-mentioned conventional technique for performing preformat recording of the servo signal, the address information signal, and the reproduction clock signal with a magnetic head using a special servo track writing device has the following problems.

First, recording with a magnetic head basically is linear recording achieved by relative movement between the head and a medium. Therefore, the above-mentioned method in which recording is performed using a special servo track writing device while the position of a magnetic head is controlled precisely requires a lot of time for preformat recording. In addition, the special servo track writing device is quite expensive, and thus an increased cost is needed for preformat recording.

Second, a recording magnetic field is broadened by a spacing between a head and a medium and by a pole shape of the recording head. Therefore, the magnetization transition lacks steepness at track edges with respect to which preformat recording was performed. In the current tracking servo technique, the position of the head is detected based on a change in reproduction output amplitude when the head deviates from the track to be scanned.

Thus, with respect to the track in which signals are preformat-recorded, it is necessary to achieve not only an excellent S/N ratio when the head scans the track precisely as in the case of reproducing data information signals recorded between servo areas, but also a sharp change in reproduction output amplitude when the head deviates from the track to be scanned, i.e., sharp off-track characteristics.

The above-mentioned problem of a lack of steepness in magnetization transition is incompatible with the needs of sharp off-track characteristics, and makes it difficult to achieve a technique of precise tracking servo that will be used for recording signals in submicron tracks in the future.

To solve the above-mentioned two problems in preformat recording with a magnetic head, there is a technique of using a master information carrier including a base on which a ferromagnetic thin film pattern corresponding to preformat information signals is formed. According to this technique, a surface of the master information carrier is brought into contact with a surface of a magnetic recording medium, and the ferromagnetic thin film pattern formed on the master information carrier is magnetized, thereby recording a magnetization pattern corresponding to the ferromagnetic thin film pattern onto the magnetic recording medium (see JP 10(1998)-40544 A).

This preformat recording technique makes it possible to perform favorable and efficient preformat recording without sacrificing other important performances such as an S/N ratio of the recording medium and an interface performance.

With an increase in the density of hard disk drives, a finer ferromagnetic thin film pattern is required to be formed on a master information carrier. While high integration of large-scale integrated circuits (LSI) requires development of a technique for forming a high-density pattern in photolithography and of a resist material, a higher-density master information carrier also requires the same development.

As a photolithography device, a mask aligner, a stepper, or the like is used. As a pattern becomes finer, a wavelength of a light source shifts to a short-wavelength side, e.g., a g-line light source (436 nm), an i-line light source (365 nm), or an excimer laser light source (248 nm). Meanwhile, the development of a resist material also is being carried out to adapt the material to an exposure wavelength.

In contrast to a stepper, which requires shots to be pieced together with high accuracy, a mask aligner, which is capable of exposing an entire surface of a wafer to light with a single shot, is low in installation unit cost and often used for thin-film component devices other than an LSI. However, a mask aligner has a lower pattern resolution than a stepper, and thus generally is not suitable for forming a fine pattern on the order of submicrons. To solve this problem, JP 2003-029424 A discloses the following method. Herein, a stepped resist and a photomask are brought into contact with each other, evacuation is performed through a recessed portion of the stepped resist (hereinafter, refereed to as an “air-evacuating recess”), and then the stepped resist is exposed to light. This method achieves enhanced contact between the resist and the photomask since an air gap therebetween is removed. Consequently, it is possible to obtain a high-resolution pattern even with a mask aligner.

In the above-mentioned method using a master information carrier, the shape and pattern of a ferromagnetic thin film formed on the master information carrier that correspond to digital signals are preformat-recorded on a magnetic recording medium. Accordingly, in order to achieve favorable magnetic signal characteristics, the pattern of the ferromagnetic thin film is required to be formed on the master information carrier accurately.

FIGS. 17(A) to (D) are cross-sectional views showing the method for forming a resist pattern disclosed in JP 2003-029424 A. FIG. 18 is a plan view schematically showing the relationship among a resist protrusion (a protrusion on a resist film) (252), an air-evacuating recess (251), and resist depressions (21). Each of the cross sections shown in FIGS. 17(A) to (D) corresponds to a cross section taken along a line E-E′ in FIG. 18. FIG. 19 shows a cross section taken along a line F-F′ in FIG. 18.

FIG. 17(A) shows an exposure process for forming an air-evacuating recess, and FIG. 17(B) shows the state where the air-evacuating recess has been formed. As shown in FIG. 17(A), a region other than the region in which a pattern is to be formed on a resist film 2 applied onto a non-magnetic base 1 is exposed to UV light 4 through a photomask 3 and developed. As a result, an air-evacuating recess 251 and a resist protrusion 252 are formed alternately on a surface of the resist film 2 as shown in FIG. 17(B).

FIG. 17(C) shows an exposure process for forming a pattern, and FIG. 17(D) shows the state where the pattern 211 has been formed. As shown in FIG. 17(C), a photomask 31 is brought into contact with the resist protrusion 252, and evacuation is performed through the recess 251 in directions shown by arrows 7. As a result, contact between the photomask 31 and the resist protrusion 252 is enhanced. In this state, the resist protrusion 252 is exposed to the UV light 4 and developed, thereby forming predetermined resist depressions 21 on the resist protrusion 252 as shown in FIG. 17(D).

According to the method disclosed in JP 2003-029424 A, the resist depressions 21 are formed in isolation only in a region of the resist protrusion 252 as shown in the plan view of the obtained pattern in FIG. 18.

Positive resists, which generally are used as high-resolution resists, allow polymers to be decomposed and become soluble in an alkaline developing solution by exposure as shown in FIG. 20. However, a nitrogen gas is generated when the polymers are decomposed.

In the above-mentioned method disclosed in JP 2003-029424 A, as shown in FIG. 19, such a reaction of the resist deforms the photomask and the resist due to a nitrogen gas 41 generated from the resist film 2 in exposure, so that a gap is created at a contact portion between the photomask 31 and the resist protrusion 252. When a gap is created at the contact portion by such deformation, the UV light 4 is diffracted through the gap to reach portions other than the-portion corresponding to the pattern in exposure, resulting in a deformed resist pattern. In FIG. 19, an example of such deformation of the photomask 31 is shown by broken lines 31a.

FIG. 21 is a plan view showing an example of such a deformed resist pattern. In this example, the pattern has a larger line width than a design line width due to the diffraction of the UV light 4 as mentioned above. In an extreme example, masked portions of the resist are all exposed to light, which may result in a connected pattern after development.

As described above, the above-mentioned conventional technique has a problem that there is a limit to achieving a fine pattern due to diffraction of the UV light 4.

### SUMMARY OF THE INVENTION

The present invention solves the above-mentioned conventional problem, and its object is to provide a method for forming a resist pattern that allows a fine pattern to be formed by preventing diffraction of light in exposure.

In order to achieve the above-mentioned object, a method for forming a resist pattern according to the present invention includes: a step of forming a resist film on a surface of a base; a step of forming a protrusion and an air-evacuating recess on the resist film by exposing the resist film to light and developing the resist film; a step of bringing the resist film and a photomask in which a pattern is formed into close contact with each other by performing evacuation through the air-evacuating recess in a state where the photomask is superimposed on the resist film; and a step of exposing a portion of the resist film that corresponds to the pattern of the photomask to light. The pattern of the photomask is formed so as to extend from a region facing the protrusion to a region facing the air-evacuating recess on the resist film.

A first method for manufacturing a master information carrier according to the present invention includes: a step of forming a resist film on a surface of a non-magnetic base; a step of forming a protrusion and an air-evacuating recess on the resist film by exposing the resist film to light and developing the resist film; a step of bringing the resist film and a photomask in which a pattern is formed into close contact with each other by performing evacuation through the air-evacuating recess in a state where the photomask is superimposed on the resist film; a step of forming a resist depression such that the surface of the non-magnetic base is exposed at a bottom of the resist depression, by exposing a portion of the resist film that corresponds to the pattern of the photomask to light and developing the portion; a step of depositing a ferromagnetic thin film on a surface of the resist film and the resist depression; and a step of forming a ferromagnetic thin film pattern on the surface of the non-magnetic base by removing the resist film together with the ferromagnetic thin film deposited on the surface of the resist film. The pattern of the photomask is formed so as to extend from a region facing the protrusion on the resist film to a region facing the air-evacuating recess on the resist film.

A second method for manufacturing a master information carrier according to the present invention includes: a step of forming a resist film on a surface of a non-magnetic base; a step of forming a protrusion and an air-evacuating recess on the resist film by exposing the resist film to light and developing the resist film; a step of bringing the resist film and a photomask in which a pattern is formed into close contact with each other by performing evacuation through the air-evacuating recess in a state where the photomask is superimposed on the resist film; a step of forming a resist depression such that the surface of the non-magnetic base is exposed at a bottom of the resist depression, by exposing a portion of the resist film that corresponds to the pattern of the photomask to light and developing the portion; a step of forming a base depression on the exposed non-magnetic base by performing etching using the resist film as a mask; a step of depositing a ferromagnetic thin film on a surface of the resist film and a bottom of the base depression so that the ferromagnetic thin film is buried in the base depression; and a step of forming a ferromagnetic thin film pattern on the non-magnetic base by removing the resist film together with the ferromagnetic thin film deposited on the surface of the resist film while leaving the ferromagnetic thin film buried in the base depression. The pattern of the photomask is formed so as to extend from a region facing the protrusion on the resist film to a region facing the air-evacuating recess on the resist film.

A method for manufacturing a magnetic recording medium according to the present invention includes: a step of manufacturing a master information carrier in which a ferromagnetic thin film pattern corresponding to an information signal is formed on a non-magnetic base; and a step of recording magnetization information corresponding to the ferromagnetic thin film pattern onto a magnetic recording medium by application of an external magnetic field in a state where the master information carrier is disposed so as to be opposed to a surface of the magnetic recording medium. The step of manufacturing a master information carrier includes a step of forming a resist pattern for forming the ferromagnetic thin film pattern. The step of forming a resist pattern includes: a step of forming a resist film on the non-magnetic base; a step of forming a protrusion and an air-evacuating recess on the resist film by exposing the resist film to light and developing the resist film; a step of bringing the resist film and a photomask in which a pattern is formed into close contact with each other by performing evacuation through the air-evacuating recess in a state where the photomask is superimposed on the resist film; and a step of exposing a portion of the resist film that corresponds to the pattern of the photomask to light. The pattern of the photomask is formed so as to extend from a region facing the protrusion to a region facing the air-evacuating recess on the resist film.

A method for manufacturing a magnetic recording/reproducing apparatus according to the present invention includes a step of mounting a magnetic recording medium, on which magnetization information corresponding to a ferromagnetic thin film pattern is recorded, on a rotating part. In the method, the magnetic recording medium is manufactured by the above-mentioned method.

A magnetic recording/reproducing apparatus according to the present invention includes: a magnetic recording medium manufactured by the above-mentioned method; a thin film magnetic head; a supporting member for supporting the thin film magnetic head so that the thin film magnetic head is opposed to the magnetic recording medium; rotating means for rotating the magnetic recording medium; moving means for moving the thin film magnetic head parallel to a surface of the magnetic recording medium, the moving means being connected with the supporting member; and processing means for exchanging signals with the thin film magnetic head, controlling rotation of the magnetic recording medium, and controlling movement of the thin film magnetic head, the processing means being electrically connected with the thin film magnetic head, the rotating means, and the moving means.

According to the present invention, contact between a photomask and a protrusion on a resist film in exposure is enhanced, so that the diffraction of light in pattern exposure can be prevented, resulting in a pattern in a finer and favorable shape.

These and other advantages of the present invention will become apparent to those skilled in the art upon reading and understanding the following detailed description with reference to the accompanying figures.

### BRIEF DESCRIPTION OF THE DRAWINGS

FIGS. 1(A) to (D) show a method for forming a resist pattern according to one embodiment of the present invention; (A) is a cross-sectional view showing an exposure process for forming an air-evacuating recess, (B) is a cross-sectional view showing the state where the air-evacuating recess 251 has been formed, (C) is a cross-sectional view showing an exposure process for forming a resist pattern, and (D) is a cross-sectional view showing the state where the resist pattern has been formed.

FIG. 2 is a plan view schematically showing an exemplary relationship among a resist protrusion, an air-evacuating recess, and resist depressions according to one embodiment of the present invention.

FIG. 3 is a plan view schematically showing another exemplary relationship among the resist protrusion, the air-evacuating recess, and the resist depressions according to one embodiment of the present invention.

FIG. 4 is a view showing the relationship between a height of a step on a resist and exposure energy according to one embodiment of the present invention.

FIG. 5 is a view showing a cross section taken along a line C-C′ in FIG. 2 in the state where a photomask is in close contact with a resist film.

FIG. 6 is a perspective view showing an entire base 11 on which the air-evacuating recess 251 has been formed according to one embodiment of the present invention.

FIGS. 7 (A) to (C) show a method for manufacturing a master information carrier according to a first example of Embodiment 2 of the present invention; (A) is a cross-sectional view showing an exposure process for forming an air-evacuating recess, (B) is a cross-sectional view showing the state where the air-evacuating recess 251 has been formed, and (C) is a cross-sectional view showing an exposure process for forming a resist pattern.

FIGS. 8 (A) to (C) are cross-sectional views showing processes subsequent to FIG. 7(C); (A) is a cross-sectional view showing the state where the resist pattern has been formed, (B) is a cross-sectional view showing a process for forming a ferromagnetic thin film pattern 63, and (C) is a cross-sectional view showing the state where the ferromagnetic thin film pattern has been formed.

FIG. 9 is an enlarged perspective view showing the exposure process in FIG. 7(C) more specifically.

FIG. 10 is a plan view showing resist depressions 21 obtained after exposure according to one embodiment of the present invention.

FIGS. 11 (A) to (D) show a method for manufacturing a master information carrier according to a second example of Embodiment 2 of the present invention; (A) is a cross-sectional view showing an exposure process for forming an air-evacuating recess, (B) is a cross-sectional view showing the state where the air-evacuating recess 251 has been formed, (C) is a cross-sectional view showing an exposure process for forming a resist pattern, and (D) is a cross-sectional view showing the state where the resist pattern has been formed.

FIGS. 12 (A) to (D) are cross-sectional views showing processes subsequent to FIG. 11(D); (A) is a cross-sectional view showing an etching process for forming base depressions, (B) is a cross-sectional view showing the state where the base depressions 13 have been formed, (C) is a cross-sectional view showing a process for forming a ferromagnetic thin film, and (D) is a cross-sectional view showing the state where the ferromagnetic thin film 6 is buried in the base depressions.

FIG. 13 is a schematic view showing a method for manufacturing a magnetic recording medium according to one embodiment of the present invention.

FIG. 14 is a schematic view showing a magnetic recording/reproducing apparatus according to one embodiment of the present invention.

FIG. 15 is a plan view showing a resist pattern for forming a thin film coil according to one embodiment of the present invention.

FIG. 16 is a plan view showing a resist pattern for forming a magnetic film of a thin film head according to one embodiment of the present invention.

FIGS. 17 (A) to (D) show an exemplary conventional method for forming a resist pattern; (A) is a cross-sectional view showing an exposure process for forming an air-evacuating recess, (B) is a cross-sectional view showing the state where the air-evacuating recess 251 has been formed, (C) is a cross-sectional view showing an exposure process for forming a resist pattern, and (D) is a cross-sectional view showing the state where the resist pattern has been formed.

FIG. 18 is a plan view schematically showing an exemplary relationship among a resist protrusion, an air-evacuating recess, and resist depressions according to a conventional method.

FIG. 19 is a view showing a cross section taken along a line F-F′ in FIG. 18.

FIG. 20 is a view for explaining how a nitrogen gas is generated in exposure.

FIG. 21 is a plan view showing an exemplary resist pattern according to a conventional method.

### DETAILED DESCRIPTION OF THE INVENTION

According to a method for forming a resist pattern and a method for manufacturing a master information carrier of the present invention, a nitrogen gas generated from an exposed portion of a resist film in exposure can be discharged through an air-evacuating recess easily, so that it is possible to prevent a gap from being created at a contact portion between a protrusion on the resist film and a photomask in exposure. Therefore, contact between the photomask and the protrusion on the resist film is enhanced, so that the diffraction of light in pattern exposure can be prevented, resulting in a resist pattern in a finer and favorable shape.

According to a method for manufacturing a magnetic recording medium, a method for manufacturing a magnetic recording/reproducing apparatus, and a magnetic recording/reproducing apparatus of the present invention, the accuracy of an information signal transferred from a master information carrier to a magnetic recording medium can be increased, which is advantageous for achieving a large capacity.

Further, in the method for manufacturing a magnetic recording medium and the magnetic recording/reproducing apparatus, it is preferable that the information signal is a signal for use in tracking servo.

With such a configuration, a length of magnetization reversal of the tracking servo signal transferred and recorded onto the magnetic recording medium is reduced, whereby the head-positioning accuracy in a track width direction is increased, which is advantageous for achieving a large capacity.

Hereinafter, one embodiment of the present invention will be described with reference to the drawings.

(Embodiment 1)

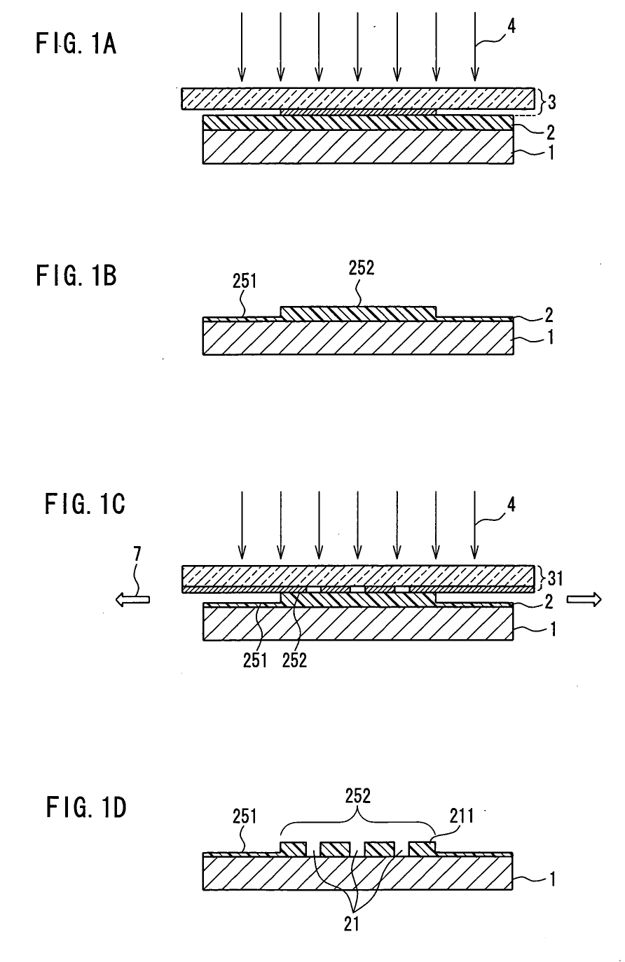

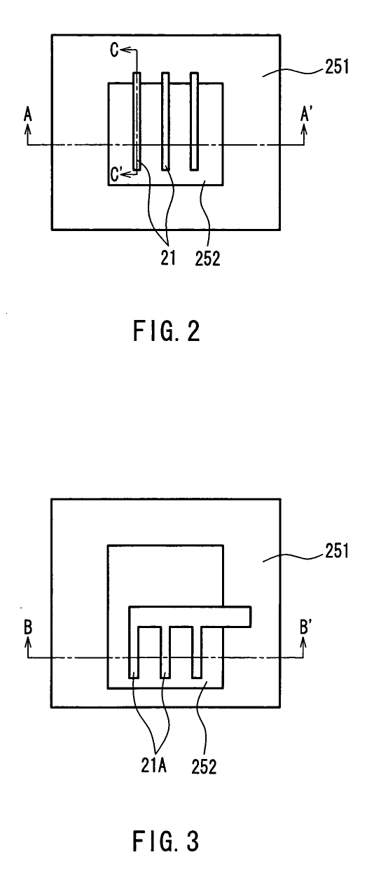

FIGS. 1(A) to (D) are cross-sectional views showing a method for forming a resist pattern according to Embodiment 1. FIG. 2 is a plan view schematically showing an exemplary relationship among a resist protrusion (a protrusion on a resist film), an air-evacuating recess, and resist depressions. FIG. 3 is a plan view schematically showing another exemplary relationship among the resist protrusion, the air-evacuating recess, and the resist depressions. FIGS. 2 and 3 show exemplary relationships among the resist protrusion, the air-evacuating recess, and a photomask pattern, and this embodiment can be applied to the formation of a resist pattern in the manufacture of a master information carrier or the like as described later in detail.

Each of the cross sections shown in FIGS. 1(A) to (D) corresponds to a cross section taken along a line A-A′ in FIG. 2 or a line B-B′ in FIG. 3.

FIG. 1(A) shows an exposure process for forming an air-evacuating recess 251, and FIG. 1(B) shows the state where the air-evacuating recess 251 has been formed. As shown in FIG. 1(A), a base 1 is spin-coated with a resist film 2, upon which low-temperature baking is performed. Then, the resist film 2 is exposed to UV light 4 through a photomask 3 and developed by the use of a photolithography technique. As a result, the resist film 2 has an uneven surface with the air-evacuating recess 251 and a resist protrusion 252 as shown in FIG. 1(B).

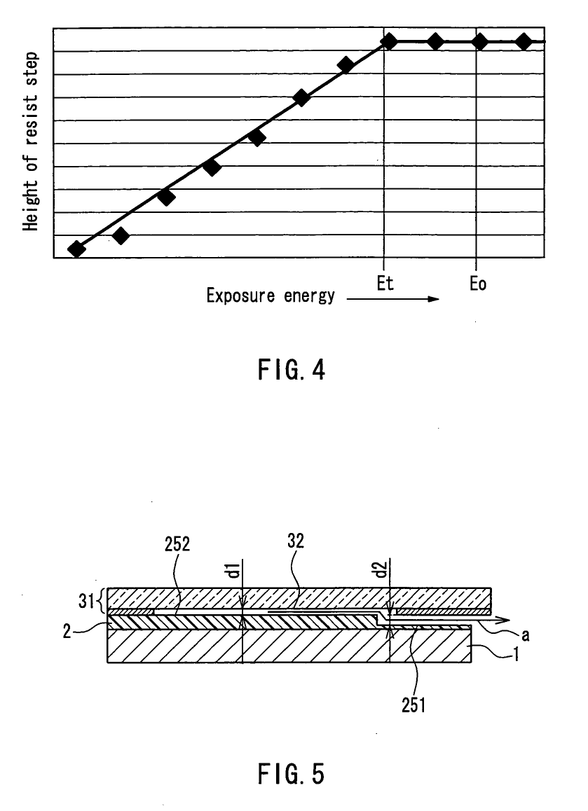

FIG. 4 shows the relationship between a degree of unevenness (a height of a step on the resist) and exposure energy. When a value of exposure energy is smaller than a threshold exposure energy value (Et) with respect to a resist film thickness, the resist film 2 in a thickness corresponding to the exposure energy remains on the base 1. On the other hand, when the value of exposure energy is larger than the threshold exposure energy value (Et), an exposed portion of the resist film 2 is removed completely, resulting in a step having a height equivalent to the resist film thickness.

FIG. 1(C) shows an exposure process for forming a resist pattern, and FIG. 1(D) shows the state where the resist pattern has been formed. Initially, a photomask 31 in which a predetermined pattern is formed is brought into contact with a surface of the resist protrusion 252, and then a gap between a base holder (not shown) and the photomask 31 is sealed hermetically. Further, evacuation is performed from an outer circumference of the base 1 in directions shown by arrows 7 through the air-evacuating recess 251 extending to the outer circumference of the base 1. Since air is released by the evacuation, the photomask 31 and the resist film 2 are brought into close contact with each other. In this state, the resist film 2 is exposed to the UV light 4 with optimum exposure energy (Eo), so that a resist pattern 211 having resist depressions 21 corresponding to the photomask pattern is formed as shown in FIG. 1(D).

In an example shown in FIG. 2, the resist depressions 21 are arranged so as to extend from a region of the protrusion 252 to the air-evacuating recess 251. In an example shown in FIG. 3, resist depressions 21A are arranged such that they are connected to each other on the resist protrusion 252 and a part of the resist depressions 21A extends to the air-evacuating recess 251. This means that in the state where the photomask 31 is superimposed on the resist protrusion 252, the photomask pattern is formed so as to extend from a region facing the resist protrusion 252 to a region facing the air-evacuating recess 251.

FIG. 5 shows a cross section taken along a line C-C′ in FIG. 2 in the state where the photomask 31 is in close contact with the resist film 2. In a portion in which a photomask pattern 32 is formed, a space d1 is formed between the resist protrusion 252 and the photomask 31, and a space d2 is formed between the air-evacuating recess 251 and the photomask 31. Since the space d1 and the space d2 are connected, a gas is allowed to circulate between these spaces.

Accordingly, a nitrogen gas generated from the exposed portion of the resist film 2 in exposure can be discharged easily through the air-evacuating recess 251 on the resist film 2 as shown by an arrow a in FIG. 5.

As a result, it is possible to prevent a gap from being created at a contact portion between the resist protrusion 252 and the photomask 31 in exposure, and thus contact between the photomask 31 and the resist protrusion 252 can be enhanced. Consequently, the diffraction of light in exposure can be prevented, resulting in a resist pattern in a finer and favorable shape.

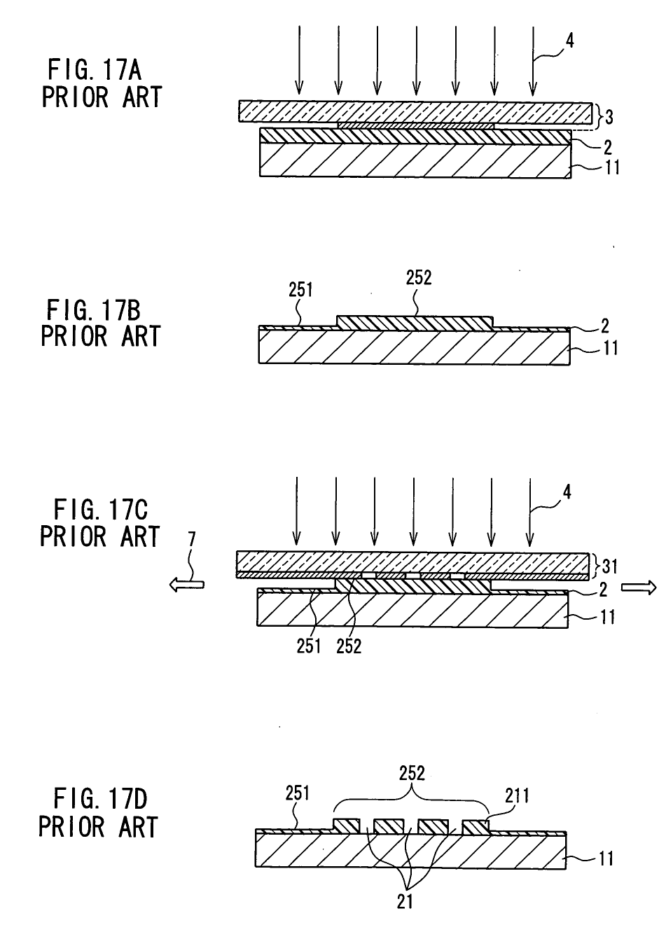

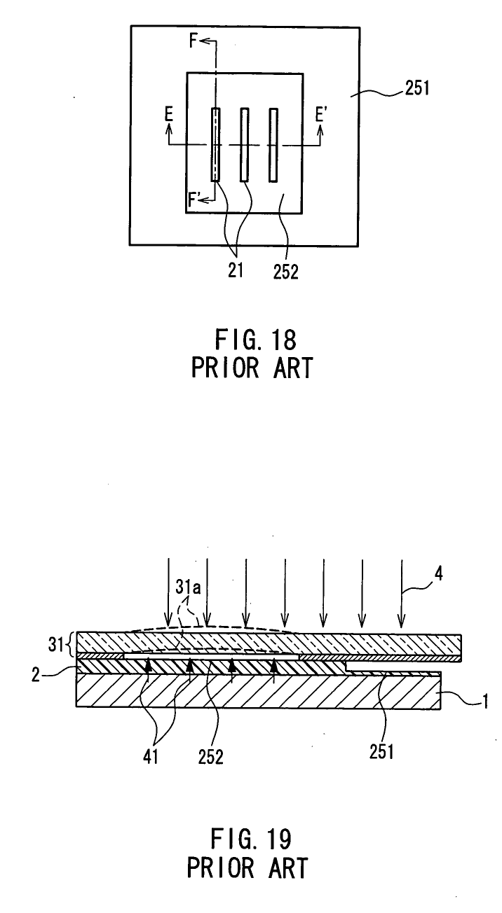

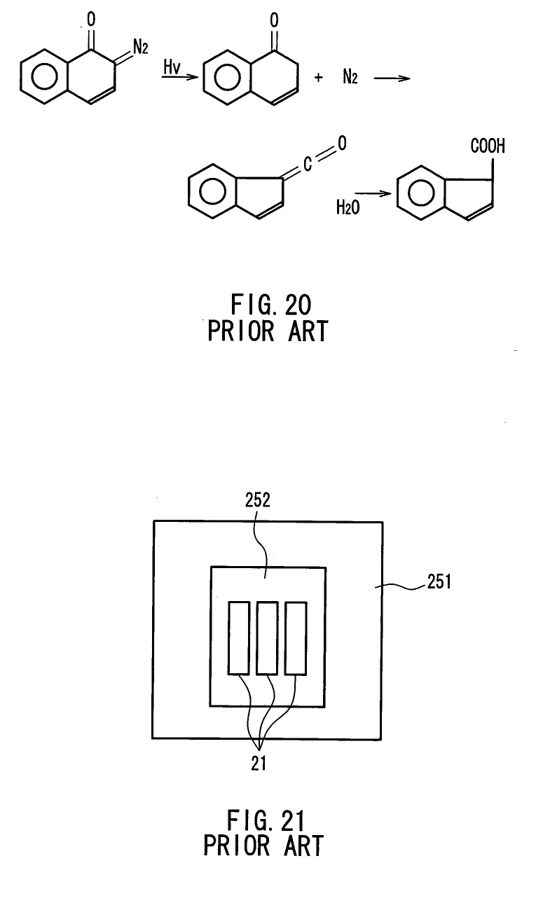

In the case of forming the pattern with a mask aligner, the limit of the line width (width of the resist depression 21) according to the conventional technique shown in FIG. 17 was 0.5 μm. In contrast, according to this embodiment, a line width of 0.3 μm was achieved. That is, according to this embodiment, since a gap is prevented from being created at the contact portion between the resist and the photomask, a mask aligner is allowed to achieve a smaller line width beyond the above-mentioned limit, whereby a high-resolution pattern can be obtained even with a mask aligner.

Herein, since a mask aligner exposes a surface of a wafer to light with a single shot, there is no need to piece together the pattern. Thus, the accuracy of the pattern can be maintained over a wide range. For example, while a base used for a master information carrier at present has a diameter of 100 mm, a mask aligner can expose even a base having a diameter of not less than 150 mm to light with a single shot.

On the other hand, a stepper can attain even a fine pattern width of not more than 100 nm. However, an area to be exposed to light with a single shot generally is not more than 30 mm×30 mm. Thus, in order to expose a continuous pattern that ranges over a larger area than the above-mentioned area to light, there is a need to piece together the pattern. In such a case, it is difficult to piece together the pattern with high accuracy as required for a master information carrier.

Further, although a stepper can realize a high-resolution pattern, the installation or maintenance cost thereof is high. For example, the installation cost of a stepper for attaining a line width on the order of 0.3 μm, which is a line width achieved in this embodiment, is about 5 times the installation cost of a mask aligner.

Namely, according to this embodiment, in the pattern formation with a mask aligner, which achieves higher pattern accuracy due to exposure with a single shot and is more advantageous in cost than a stepper, it is possible to solve the problem of the limit of the line width due to defective contact between the photomask and the resist, whereby a higher-resolution pattern can be obtained.

(Embodiment 2)

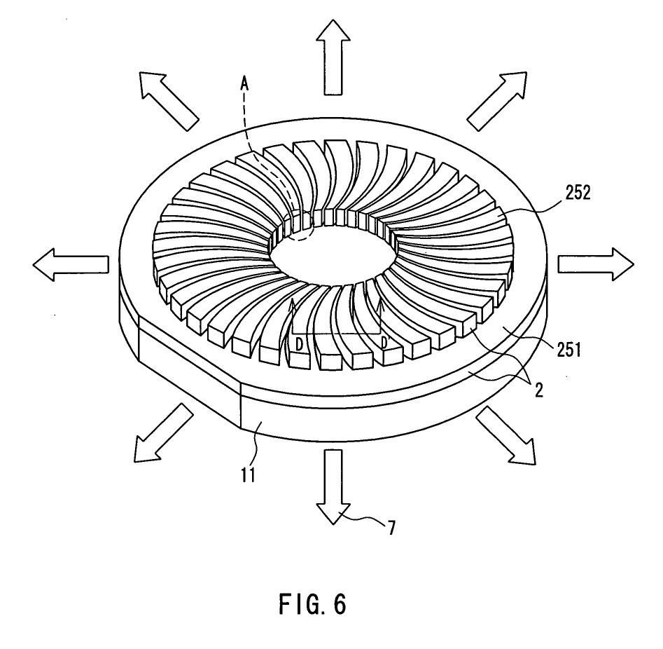

Embodiment 2 relates to a method for manufacturing a master information carrier using the method for forming a resist pattern according to Embodiment 1. FIG. 6 is a perspective view showing an entire base on which an air-evacuating recess has been formed.

In order to explain the overall configuration, a description will be given initially of the base on which the air-evacuating recess has been formed with reference to FIG. 6. A resist film 2 having an uneven surface with resist protrusions 252 and the air-evacuating recess 251 is applied onto the non-magnetic base 11. The air-evacuating recess 251 includes a groove portion extending in a substantially radial direction and an annular portion surrounding the protrusions 252 on the non-magnetic base 11. This means that the air-evacuating recess 251 extends from an inner circumference through an outer circumference to an outer space of the non-magnetic base 11.

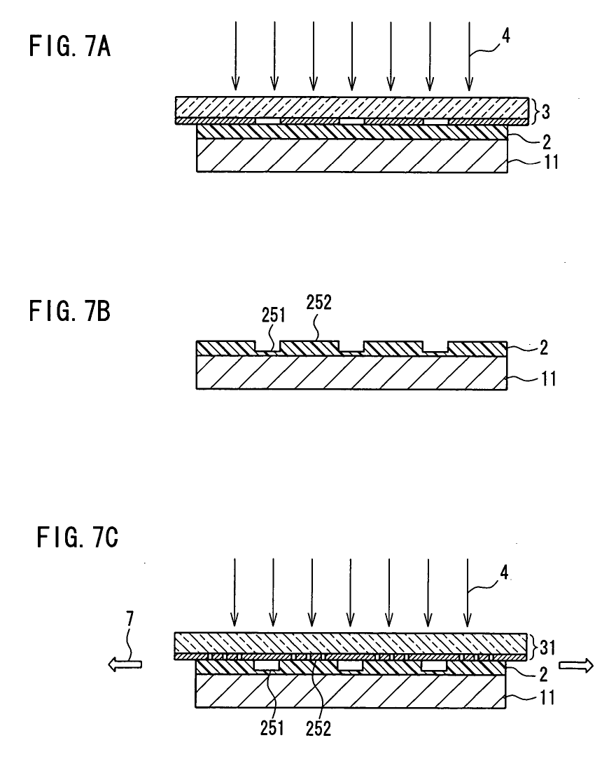

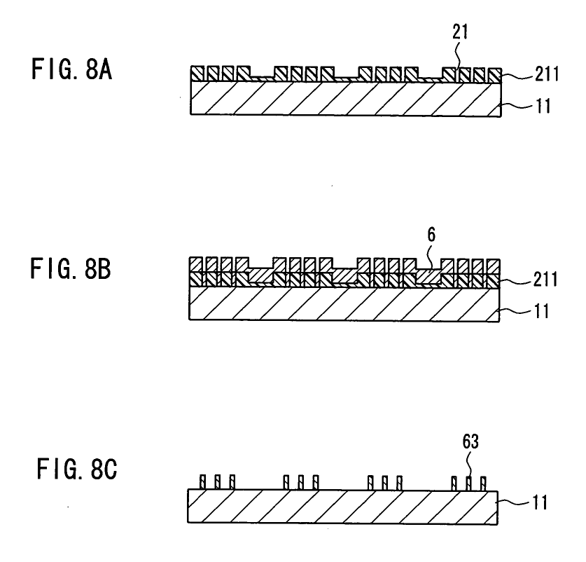

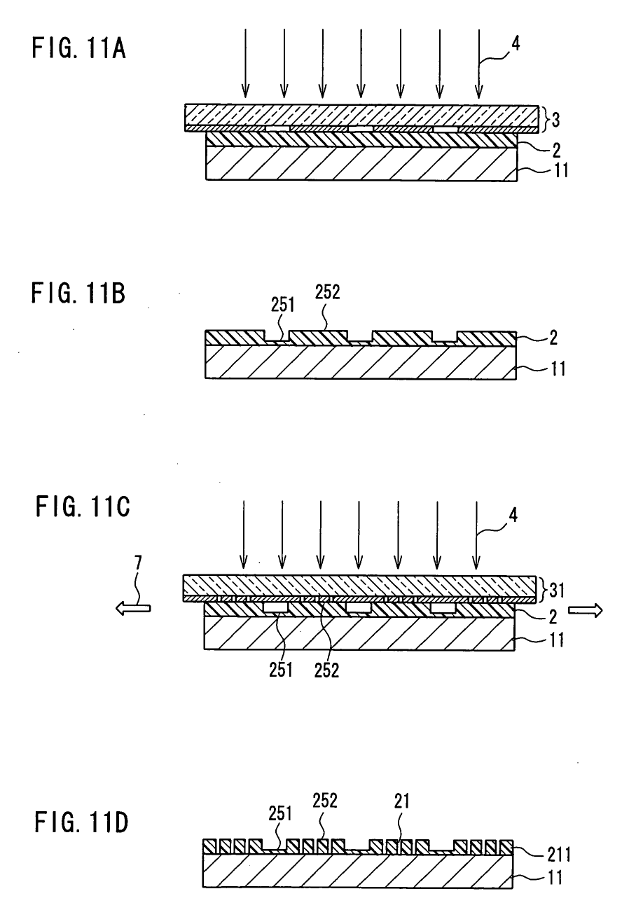

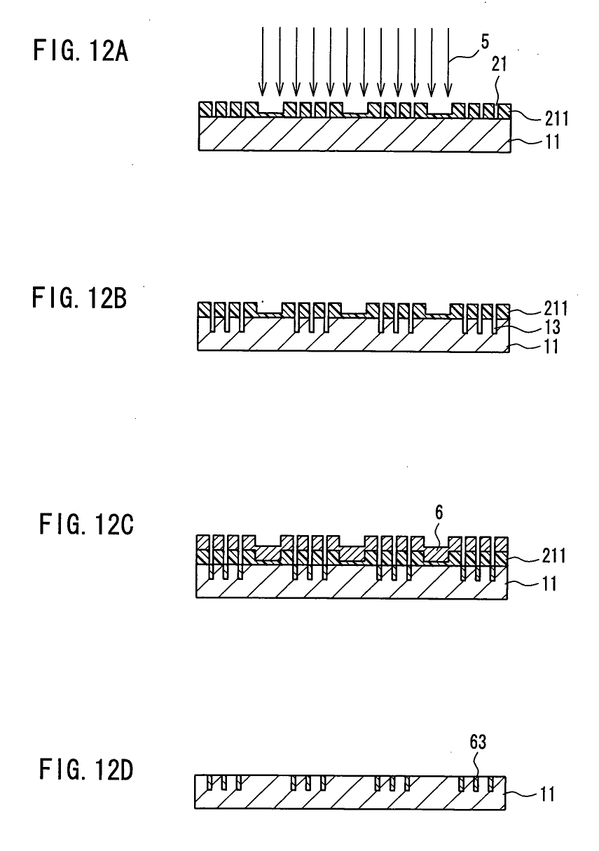

FIGS. 7(A) to (C) and FIGS. 8(A) to (C) are cross-sectional views showing a method for forming a resist pattern according to a first example of this embodiment. Each of the cross sections shown in the figures corresponds to a cross section taken along a line D-D′ in FIG. 6. This also applies to cross sections shown in FIGS. 11 to 12.

FIG. 7(A) shows an exposure process for forming the air-evacuating recess 251, and FIG. 7(B) shows the state where the air-evacuating recess 251 has been formed. As shown in FIG. 7(A), the resist film 2 applied onto the non-magnetic base 11 is exposed to UV light 4 through a photomask 3 and developed by the use of a photolithography technique. As a result, the resist film 2 has an uneven surface with the air-evacuating recess 251 and the resist protrusions 252 as shown in FIG. 7(B).

FIG. 7(C) shows an exposure process for forming a resist pattern, and FIG. 8(A) shows the state where the resist pattern has been formed. As shown in FIG. 7(C), a photomask 31 having a pattern corresponding to a digital signal is brought into contact with a surface of the resist protrusions 252, and a gap between a base holder (not shown) and the photomask 31 is sealed hermetically. Further, as shown in FIG. 6, evacuation is performed from the outer circumference of the non-magnetic base 11 in directions shown by arrows 7 through the air-evacuating recess 251 extending to the outer circumference of the non-magnetic base 1. Since air is released by the evacuation, the photomask 31 and the resist film 2 are brought into close contact with each other.

In this state, the resist film 2 is exposed to light and developed, so that a resist pattern 211 corresponding to the digital signal that has resist depressions 21 is formed as shown in FIG. 8(A).

Also in this embodiment, as in Embodiment 1, in the state where the photomask 31 is superimposed on the resist protrusions 252, the pattern of the photomask 31 is formed so as to extend from a region facing the resist protrusions 252 to a region facing the air-evacuating recess 251. Therefore, the effect of preventing the creation of a gap at a contact portion between the photomask and the resist protrusions, which was explained with reference to FIG. 5, can be achieved in this embodiment also. Further, this also applies to a second example described later.

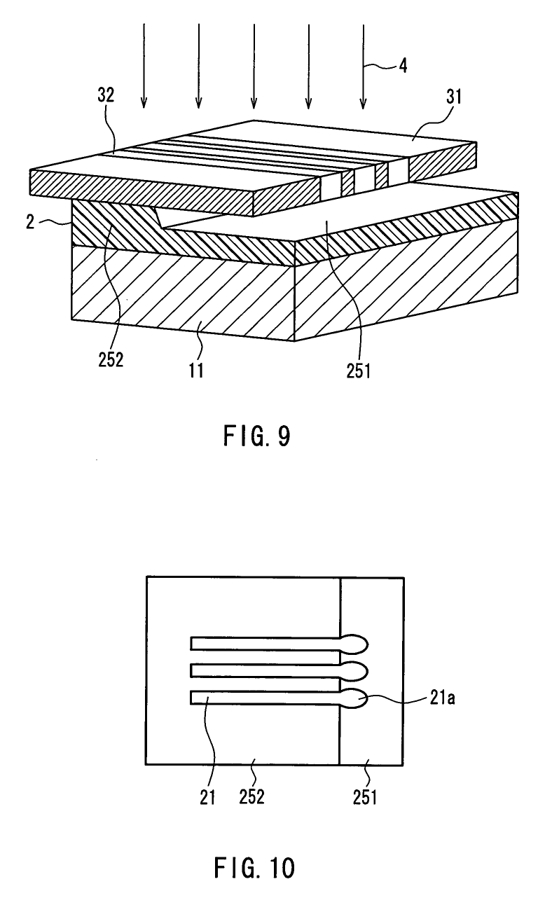

FIG. 9 is a perspective view showing the exposure process in FIG. 7(C) more specifically, which also corresponds to an enlarged view of a portion A (an inner circumferential portion of the region in which the resist pattern is formed) shown in the perspective view of FIG. 6 with the photomask. FIG. 10 is a plan view showing the resist depressions 21 obtained after exposure.

The difference between FIG. 9 and FIG. 7(C) is that FIG. 7(C) shows the configuration of a base and a light-shielding film of the photomask 31, while FIG. 9 schematically shows the functional difference between a light-transmitting portion and a light-shielding portion of the photomask 31.

Since a photomask pattern 32 also is formed in a portion facing the air-evacuating recess 251, the air-evacuating recess 251 also is exposed to light. In this case, there is a step having a height of several hundreds of nanometers between the resist protrusion 252 and the air-evacuating recess 251, and thus light passes through the step to portions other than the portion facing the photomask pattern 32 in exposure.

As a result, the resist pattern obtained after development has deformed portions as denoted by 21a in FIG. 10. In an extreme example, the deformed portions 21a may be connected to each other. However, the pattern required for a master information carrier is formed entirely on the resist protrusion 252, and thus the deformed portions 21a formed in the air-evacuating recess 251 are not particularly a problem. This also applies to the second example described later.

FIG. 8(B) shows the state where a ferromagnetic thin film 6 has been formed, and FIG. 8(C) shows the state where a ferromagnetic thin film pattern 63 has been formed. As shown in FIG. 8(B), a ferromagnetic thin film 6 is formed on the non-magnetic base 11 and the resist pattern 211. Then, an unnecessary ferromagnetic thin film 6 deposited on the resist pattern 211 is lifted off using a solvent, so that the ferromagnetic thin film pattern 63 is formed as shown in FIG. 8(C).

FIGS. 11(A) to (D) and FIGS. 12(A) to (D) show the second example of this embodiment. FIGS. 11(A) to (D) show processes from the formation of the air-evacuating recess 251 to the formation of the resist pattern 211. These processes are the same as those shown in FIGS. 7(A) to 8(A), and thus descriptions of the figures will be omitted.

FIG. 12(A) shows an etching process for forming base depressions 13, and FIG. 12(B) shows the state where the base depressions 13 have been formed. As shown in FIG. 12(A), the non-magnetic base 11 previously is etched by a reactive gas 5 using the resist pattern 211 as a mask. As a result, the base depressions 13 having a pattern corresponding to a digital signal are formed as shown in FIG. 12(B).

FIG. 12(C) shows the state where the ferromagnetic thin film 6 has been formed, and FIG. 12(D) shows the state where the ferromagnetic thin film 6 is buried in the base depressions. As shown in FIG. 12(C), the ferromagnetic thin film 6 is formed so as to be buried in the base depressions 13. Then, an unnecessary ferromagnetic thin film 6 deposited on the resist pattern 211 is lifted off, resulting in a master information carrier in which the ferromagnetic thin film pattern 63 is buried in the non-magnetic base 11 as shown in FIG. 12(D).

According to Embodiment 2, as in Embodiment 1, excellent contact is obtained between the resist protrusions 252 and the photomask 31. Thus, the resist pattern 211 can be formed accurately, resulting in a master information carrier having favorable pattern accuracy.

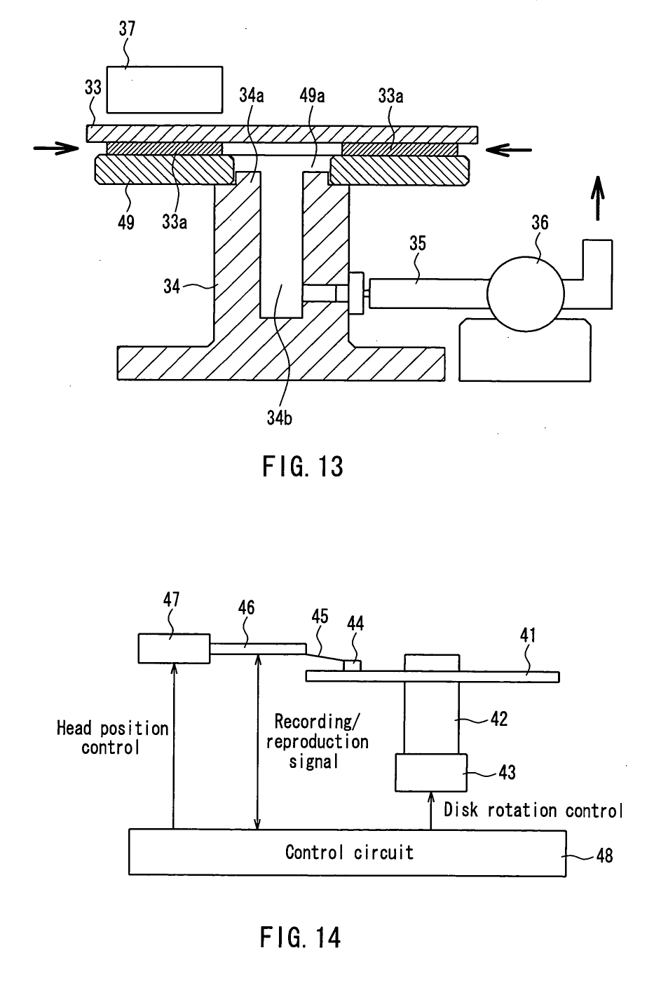

Next, a description will be given of a method for manufacturing a magnetic recording medium using the master information carrier manufactured through the above-mentioned processes. FIG. 13 is a schematic view showing a recording device for magnetically transferring and recording an information signal. In FIG. 13, a magnetic disk 49 as a magnetic recording medium is a toroidal disk having a center hole 49a. The magnetic disk 49 is configured by forming a ferromagnetic thin film containing Co and the like as principal components on a surface of a non-magnetic base by a sputtering method.

A disk-shaped master information carrier 33 is superimposed on the ferromagnetic thin film surface of the magnetic disk 49 so as to be in contact therewith. The master information carrier 33, which is manufactured by the manufacturing method as described in Embodiment 2, has a signal region 33a on a surface that is to be in contact with the magnetic disk 49. The signal region 33a is formed by the ferromagnetic thin film pattern 63 in Embodiment 2, which is a fine pattern corresponding to an information signal to be magnetically transferred and recorded onto the magnetic disk 49.

The magnetic disk 49 is held by a disk holder 34. A chuck portion 34a for positioning and holding the magnetic disk 49 is provided at an end portion of the disk holder 34. Further, a suction hole 34b is provided inside the disk holder 34. The suction hole 34b is in communication with the center hole 49a of the magnetic disk 49, and one end thereof is connected to an exhaust duct 35.

An exhaust system 36 is provided at an end of the exhaust duct 35. When activating the exhaust system 36, a negative pressure is formed in a space between the magnetic disk 49 and the master information carrier 33 through the exhaust duct 35 and the suction hole 34b of the disk holder 34. Consequently, the master information carrier 33 is urged toward the magnetic disk 49, so that the magnetic disk 49 is positioned and superimposed on the master information carrier 33.

A magnetizing head 37 applies an external magnetic field required for transferring and recording a signal from the master information carrier 33 onto the magnetic disk 49. The magnetic field applied by the magnetizing head 37 magnetizes the ferromagnetic thin film pattern formed on the master information carrier 33 that corresponds to an information signal, and a leakage flux generated from the pattern allows the information signal corresponding to the ferromagnetic thin film pattern in the signal region 33a to be recorded onto the magnetic disk 49.

Further, a magnetic recording/reproducing apparatus can be manufactured using the magnetic recording medium manufactured through the above-mentioned processes. To manufacture a magnetic recording/reproducing apparatus, which will be described later in detail with reference to FIG. 14, the magnetic recording medium on which an information signal has been recorded using the master information carrier is mounted on a rotating part.

FIG. 14 is a schematic view showing a magnetic recording/reproducing apparatus. A magnetic disk 41 as a magnetic recording medium is manufactured through the above-mentioned processes. The magnetic disk 41 is supported on a spindle 42 as a rotating part. The magnetic disk 41 is rotated by the rotation of a spindle motor 43 as rotating means via the spindle 42.

A thin film magnetic head 44 is attached to an actuator 47 as moving means via a suspension 45 and an actuator arm 46 as supporting members.

With this configuration, the thin film magnetic head 44 can be moved by the operation of the actuator 47. Further, the thin film magnetic head 44 is arranged so as to be opposed to a surface of the magnetic disk 41. Therefore, the rotation of the magnetic disk 41 and the movement of the thin film magnetic head 44 in a radial direction of the magnetic disk 41 allow reading/writing of a signal from/on nearly the entire surface of the magnetic disk 41. Further, a control circuit 48 as processing means controls the rotation of the magnetic disk 41, the position of the thin film magnetic head 44, a recording/reproduction signal, and the like.

### EXAMPLE

Hereinafter, one example of the present invention will be described. A resist film having a thickness of about 0.7 μm was applied onto a base by spin coating, which was then soft-baked with a hot plate at a temperature of 90° C. for 1 minute. Thereafter, a surface of the resist film was partially exposed to light with a UV irradiation power of 10 mW/cm² for 2 to 4 seconds and developed, thereby forming an uneven resist with steps having a height of about 0.1 to 0.5 μm.

Then, a photomask in which a predetermined pattern is formed and protrusions on the resist film were brought into close contact with each other by evacuation, and then the resist film was exposed to light with optimum exposure energy suitable for a resist film thickness of 0.7 μm and developed, thereby forming a resist pattern. A line width of the resist pattern was as small as 0.3 μm. Further, by using this resist pattern, a shape pattern of a ferromagnetic thin film corresponding to an information signal for use in tracking servo was formed on the base.

A signal was preformat-recorded on a magnetic recording medium using a master information carrier manufactured in this manner, and using this magnetic recording medium, a magnetic recording/reproducing apparatus as shown in FIG. 14 was manufactured. The signal recorded on the magnetic recording medium was read with a head (thin film magnetic head 44) and evaluated. As a result, it was confirmed that the signal was recorded as designed even when the line width of the pattern is as small as 0.3 μm.

On the other hand, such an evaluation also was performed on a signal that was recorded on a magnetic recording medium using a master information carrier on which the resist pattern was formed by the conventional method as shown in FIGS. 17. As a result, a reproduction signal as designed was not obtained when the line width of the pattern is reduced to 0.5 μm.

As a line width of the pattern becomes smaller, a length of magnetization reversal of a tracking servo signal transferred and recorded on the magnetic recording medium is reduced. Accordingly, the resolution in a track width direction based on the signal is enhanced, and the head-positioning accuracy is increased. The head-positioning accuracy in this case is proportional to an inverse number of the length of magnetization reversal. Thus, when the line width is reduced from 0.5 μm to 0.3 μm, the head-positioning accuracy in the track width direction becomes about 1.7 times (0.5 μm/0.3 μm) higher.

When the length of magnetization reversal of the transferred-and-recorded tracking servo signal is reduced, assuming that the area occupied by the tracking servo signal is the same, a repetition period of the signal in the area can be increased by an amount equivalent to a reduced length of magnetization reversal. As a result, due to the averaging effect of the signal, an SIN ratio of the signal is increased, and the head-positioning accuracy can be increased. The head-positioning accuracy in this case is proportional to a square root of an inverse number of the length of magnetization reversal. Thus, when the line width is reduced from 0.5 μm to 0.3 μm, the head-positioning accuracy in the track width direction becomes about 1.3 times higher.

According to these two effects, when the line width is reduced from 0.5 μm to 0.3 μm, the head-positioning accuracy in the track width direction becomes about 2.2 times (1.7×1.3) higher. That is, the density in the track width direction can be 2.2 times higher, which contributes to obtaining a magnetic recording/reproducing apparatus having a larger capacity.

(Embodiment 3)

While Embodiment 2 deals with examples of forming a pattern of a master information carrier, Embodiment 3 shows still another example.

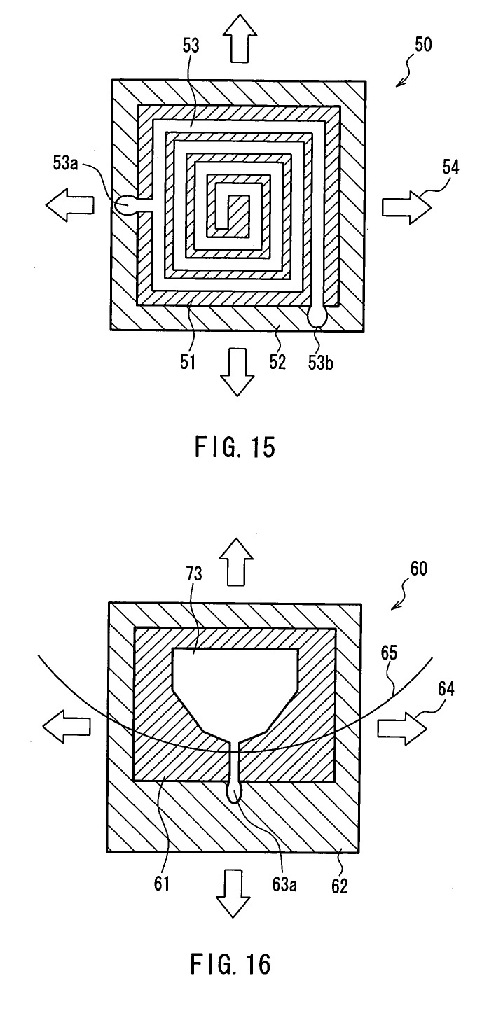

FIG. 15 is a plan view showing a resist pattern for forming a thin film coil. A resist film 50 has an uneven surface with a protrusion 51 and an air-evacuating recess 52. In the state where a photomask (not shown) is superimposed on the resist film 50, evacuation is performed in directions shown by arrows 54 through the air-evacuating recess 52, so that the protrusion 51 and the photomask are brought into close contact with each other. In this state, a portion corresponding to a pattern of the photomask is exposed to light and developed, thereby forming a resist depression 53. FIG. 15 shows the state where the resist depression 53 has been formed.

Also in the example shown in this figure, the pattern of the photomask is formed so as to extend from the protrusion 51 to the air-evacuating recess 52. Thus, it is possible to prevent a gap from being created at a contact portion between the protrusion 51 and the photomask in exposure. As a result, contact between the protrusion 51 and the photomask is enhanced, resulting in a resist pattern in a favorable shape.

Further, as in the example shown in FIG. 10, the pattern in the air-evacuating recess 52 has deformed portions 53a and 53b. However, a portion of the thin film coil corresponding to the deformed portion 53a is not effective as a conductor, and thus such a pattern deformation is not a problem. Further, a portion of the thin film coil corresponding to the deformed portion 53b is to be connected to an external connection terminal, and thus such a pattern deformation is not a problem.

FIG. 16 is a plan view showing a resist pattern for forming a magnetic film of a thin film head. A resist film 60 has an uneven surface with a protrusion 61 and an air-evacuating recess 62. In the state where a photomask (not shown) is superimposed on the resist film 60, evacuation is performed in directions shown by arrows 64 through the air-evacuating recess 62, so that the protrusion 61 and the photomask are brought into close contact with each other. In this state, a portion corresponding to a pattern of the photomask is exposed to light and developed, thereby forming a resist depression 73. FIG. 16 shows the state where the resist depression 73 has been formed.

Also in the example shown in this figure, the pattern of the photomask is formed so as to extend from the protrusion 61 to the air-evacuating recess 62. Thus, it is possible to prevent a gap from being created at a contact portion between the protrusion 61 and the photomask in exposure. As a result, contact between the protrusion 61 and the photomask is enhanced, resulting in a resist pattern in a favorable shape.

Further, as in the example shown in FIG. 10, the resist depression 73 in the air-evacuating recess 62 has a deformed portion 63a. However, the magnetic film will be lapped to a position corresponding to a position shown by a curved line 65 when completed as a device. This means that a portion corresponding to the deformed portion 63a is to be removed in the end, and thus such a pattern deformation is not a problem.

Each embodiment of the present invention has been described by way of examples as above. However, the present invention is not limited to these examples, and can be applied to the manufacture of various parts, devices, or the like that require the formation of a resist pattern during their manufacturing process.

As described above, according to the present invention, contact between a photomask and a protrusion on a resist film in exposure is enhanced, so that the diffraction of light in pattern exposure can be prevented, resulting in a pattern in a finer and favorable shape. Consequently, the present invention is useful for forming a resist pattern in the manufacture of, for example, a master information carrier or the like.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A method for forming a resist pattern comprising:
a step of forming a resist film on a surface of a base;
a step of forming a protrusion and an air-evacuating recess on the resist film by exposing the resist film to light and developing the resist film;
a step of bringing the resist film and a photomask in which a pattern is formed into close contact with each other by performing evacuation through the air-evacuating recess in a state where the photomask is superimposed on the resist film; and
a step of exposing a portion of the resist film that corresponds to the pattern of the photomask to light,
wherein the pattern of the photomask is formed so as to extend from a region facing the protrusion to a region facing the air-evacuating recess on the resist film.

2. A method for manufacturing a master information carrier comprising:
a step of forming a resist film on a surface of a non-magnetic base;
a step of forming a protrusion and an air-evacuating recess on the resist film by exposing the resist film to light and developing the resist film;
a step of bringing the resist film and a photomask in which a pattern is formed into close contact with each other by performing evacuation through the air-evacuating recess in a state where the photomask is superimposed on the resist film;
a step of forming a resist depression such that the surface of the non-magnetic base is exposed at a bottom of the resist depression, by exposing a portion of the resist film that corresponds to the pattern of the photomask to light and developing the portion;
a step of depositing a ferromagnetic thin film on a surface of the resist film and the resist depression; and
a step of forming a ferromagnetic thin film pattern on the surface of the non-magnetic base by removing the resist film together with the ferromagnetic thin film deposited on the surface of the resist film,
wherein the pattern of the photomask is formed so as to extend from a region facing the protrusion on the resist film to a region facing the air-evacuating recess on the resist film.

3. A method for manufacturing a master information carrier comprising:
a step of forming a resist film on a surface of a non-magnetic base;
a step of forming a protrusion and an air-evacuating recess on the resist film by exposing the resist film to light and developing the resist film;
a step of bringing the resist film and a photomask in which a pattern is formed into close contact with each other by performing evacuation through the air-evacuating recess in a state where the photomask is superimposed on the resist film;
a step of forming a resist depression such that the surface of the non-magnetic base is exposed at a bottom of the resist depression, by exposing a portion of the resist film that corresponds to the pattern of the photomask to light and developing the portion;
a step of forming a base depression on the exposed non-magnetic base by performing etching using the resist film as a mask;
a step of depositing a ferromagnetic thin film on a surface of the resist film and a bottom of the base depression so that the ferromagnetic thin film is buried in the base depression; and
a step of forming a ferromagnetic thin film pattern on the non-magnetic base by removing the resist film together with the ferromagnetic thin film deposited on the surface of the resist film while leaving the ferromagnetic thin buried in the base depression,
wherein the pattern of the photomask is formed so as to extend from a region facing the protrusion on the resist film to a region facing the air-evacuating recess on the resist film.

4. A method for manufacturing a magnetic recording medium comprising: a step of manufacturing a master information carrier in which a ferromagnetic thin film pattern corresponding to an information signal is formed on a non-magnetic base; and a step of recording magnetization information corresponding to the ferromagnetic thin film pattern onto a magnetic recording medium by application of an external magnetic field in a state where the master information carrier is disposed so as to be opposed to a surface of the magnetic recording medium,
wherein the step of manufacturing a master information carrier includes a step of forming a resist pattern for forming the ferromagnetic thin film pattern,
wherein the step of forming a resist pattern includes:
a step of forming a resist film on the non-magnetic base;
a step of forming a protrusion and an air-evacuating recess on the resist film by exposing the resist film to light and developing the resist film;
a step of bringing the resist film and a photomask in which a pattern is formed into close contact with each other by performing evacuation through the air-evacuating recess in a state where the photomask is superimposed on the resist film; and
a step of exposing a portion of the resist film that corresponds to the pattern of the photomask to light, and
wherein the pattern of the photomask is formed so as to extend from a region facing the protrusion to a region facing the air-evacuating recess on the resist film.

5. The method for manufacturing a magnetic recording medium according to claim 4, wherein the information signal is a signal for use in tracking servo.

6. A method for manufacturing a magnetic recording/reproducing apparatus comprising a step of mounting a magnetic recording medium, on which magnetization information corresponding to a ferromagnetic thin film pattern is recorded, on a rotating part,
wherein the magnetic recording medium is manufactured by a method according to claim 4.

7. A magnetic recording/reproducing apparatus comprising:
a magnetic recording medium manufactured by a method according to claim 4;
a thin film magnetic head;
a supporting member for supporting the thin film magnetic head so that the thin film magnetic head is opposed to the magnetic recording medium;
rotating means for rotating the magnetic recording medium;
moving means for moving the thin film magnetic head parallel to a surface of the magnetic recording medium, the moving means being connected with the supporting member; and
processing means for exchanging signals with the thin film magnetic head, controlling rotation of the magnetic recording medium, and controlling movement of the thin film magnetic head, the processing means being electrically connected with the thin film magnetic head, the rotating means, and the moving means.

8. The magnetic recording/reproducing apparatus according to claim 7, wherein the information signal is a signal for use in tracking servo.
